(19) United States
(12) Patent Application Publication
(10) Pub. No.: US 2012/0308341 A1
(43) Pub. Date: Dec. 6, 2012

(54) SUBSTRATE PROCESSING APPARATUS AND METHOD OF CONTROLLING SUBSTRATE PROCESSING APPARATUS

(75) Inventors: Shigeru Ishizawa, Yamanashi (JP); Masaki Kondo, Yamanashi (JP)

(73) Assignee: TOKYO ELECTRON LIMITED

(21) Appl. No.: 13/508,589

(22) PCT Filed: Nov. 8, 2010
(86) PCT No.: PCT/JP2010/069849

§ 371 Date: May 8, 2012

(30) Foreign Application Priority Data
Nov. 9, 2009 (JP) 2009-256301

(51) Int. Cl. H01L 21/677; B25J 11/00

(52) U.S. Cl. 414/217; 414/225.01

(57) ABSTRACT

A substrate processing apparatus includes a conveying arm configured to convey a substrate and including an electrostatic chuck for attracting the substrate placed on the conveying arm; and a control unit configured to not apply a voltage for causing the electrostatic chuck to attract the substrate between electrodes of the electrostatic chuck when the substrate is placed on the conveying arm but the conveying arm is not moving, and to apply the voltage between the electrodes of the electrostatic chuck when the substrate is placed on the conveying arm and the conveying arm is moving.

### TECHNICAL FIELD

The present invention relates to a substrate processing apparatus, a substrate conveying device, and a method of controlling the substrate processing apparatus.

### BACKGROUND ART

A semiconductor device, which includes multilayer films formed on a semiconductor wafer, is manufactured by sequentially and repeatedly performing various thin-film forming processes, modification processes, oxidation and diffusion processes, annealing processes, and etching processes on the semiconductor wafer.

There exists a substrate processing apparatus, called a cluster tool, for manufacturing such a semiconductor device. The substrate processing apparatus includes multiple single-wafer processing chambers for performing various processes and a transfer chamber that are connected to each other. Different processes are sequentially performed on a semiconductor wafer in the corresponding processing chambers. This configuration makes it possible to perform various processes using one substrate processing apparatus. In such a substrate processing apparatus, a semiconductor wafer is moved between the processing chambers by a conveying arm that is provided in the transfer chamber and configured to extend, retract, and rotate. A typical conveying arm includes an electrostatic chuck that attracts a semiconductor wafer while the semiconductor wafer is being conveyed.
[Patent document 1] Japanese Laid-Open Patent Publication No. 2002-280438
[Patent document 2] Japanese Laid-Open Patent Publication No. 2004-119635

### DISCLOSURE OF INVENTION

### Problems to be Solved by the Invention

When moving a semiconductor wafer between the processing chambers, a voltage is applied to the electrodes of the electrostatic chuck of the conveying arm to attract the semiconductor wafer to the electrostatic chuck. Here, when the semiconductor wafer is attracted to the electrostatic chuck for a long period of time, it often happens that the semiconductor wafer sticks to the electrostatic chuck and becomes difficult to be detached from the conveying arm. This phenomenon is hereafter called “sticking”. For this reason, there is a demand for a substrate processing apparatus and a substrate conveying device including a conveying arm configured to prevent sticking of a semiconductor wafer, and a method of controlling the substrate processing apparatus.

There is also a demand for a cluster tool with improved throughput to reduce the manufacturing costs of semiconductor devices. Further, it is desired to reduce the power consumption of substrate processing apparatuses.

### Means for Solving the Problems

According to a first aspect of the present invention, there is provided a substrate processing apparatus that includes a conveying arm configured to convey a substrate and including an electrostatic chuck for attracting the substrate placed on the conveying arm; and a control unit configured to not apply a voltage for causing the electrostatic chuck to attract the substrate between electrodes of the electrostatic chuck when the substrate is placed on the conveying arm but the conveying arm is not moving, and to apply the voltage between the electrodes of the electrostatic chuck when the substrate is placed on the conveying arm and the conveying arm is moving.

According to a second aspect of the present invention, there is provided a substrate processing apparatus that includes a conveying arm including an electrostatic chuck for attracting a substrate placed on the conveying arm and configured to perform extending, retracting, and rotating movements to convey the substrate; and a control unit configured to not apply a voltage for causing the electrostatic chuck to attract the substrate between electrodes of the electrostatic chuck when the substrate is placed on the conveying arm and the conveying arm is performing the extending movement or the retracting movement, and to apply the voltage between the electrodes of the electrostatic chuck when the substrate is placed on the conveying arm and the conveying arm is performing the rotational movement.

According to a third aspect of the present invention, there is provided a method of controlling a substrate processing apparatus that includes a conveying arm configured to convey a substrate and including an electrostatic chuck for attracting the substrate placed on the conveying arm. The method includes a step of placing the substrate on the conveying arm; a first moving step of applying a voltage between electrodes of the electrostatic chuck of the conveying arm to attract the substrate to the conveying arm and causing the conveying arm to move the substrate; a removing step, performed after the first moving step, of removing an attraction force of the electrostatic chuck of the conveying arm; and a second moving step, performed after the removing step, of applying the voltage between the electrodes of the electrostatic chuck of the conveying arm to attract the substrate to the conveying arm and causing the conveying arm to move the substrate.

According to a fourth aspect of the present invention, there is provided a method of controlling a substrate processing apparatus that includes a conveying arm configured to convey a substrate and including an electrostatic chuck for attracting the substrate placed on the conveying arm. The method includes a step of placing the substrate on the conveying arm; a first moving step of causing the conveying arm to extend or retract to move the substrate without causing the electrostatic chuck to attract the substrate; a rotating step, performed after the first moving step, of applying a voltage between electrodes of the electrostatic chuck of the conveying arm to attract the substrate to the conveying arm and causing the conveying arm to rotate, but not to extend or retract, to move the substrate; a removing step, performed after the rotating step, of removing an attraction force of the electrostatic chuck of the conveying arm; and a second moving step, performed after the removing step, of causing the conveying arm to extend or retract to move the substrate without causing the electrostatic chuck to attract the substrate.

### BRIEF DESCRIPTION OF THE DRAWINGS

FIG. 1 is a drawing illustrating a configuration of a substrate processing apparatus according to a first embodiment;

FIG. 2 is a top view of a conveying arm;

FIG. 3 is an enlarged cross-sectional view of a conveying arm;

FIG. 4 is a timing chart (1) used to describe a method of controlling a substrate processing apparatus according to a comparative example;

FIG. 5 is a timing chart used to describe a method of controlling a substrate processing apparatus according to the first embodiment;

FIG. 6 is a drawing (1) used to describe a method of controlling a substrate processing apparatus according to the first embodiment;

FIG. 7 is a drawing (2) used to describe a method of controlling a substrate processing apparatus according to the first embodiment;

FIG. 8 is a drawing (3) used to describe a method of controlling a substrate processing apparatus according to the first embodiment;

FIG. 9 is a timing chart (2) used to describe a method of controlling a substrate processing apparatus according to a comparative example;

FIG. 10 is a timing chart used to describe a method of controlling a substrate processing apparatus according to a second embodiment;

FIG. 11 is a timing chart (3) used to describe a method of controlling a substrate processing apparatus according to a comparative example;

FIG. 12 is a timing chart used to describe a method of controlling a substrate processing apparatus according to a third embodiment;

FIG. 13 is a timing chart used to describe a method of controlling a substrate processing apparatus according to a fourth embodiment; and

FIG. 14 is a timing chart used to describe a method of controlling a substrate processing apparatus according to a fifth embodiment.

### BEST MODE FOR CARRYING OUT THE INVENTION

An aspect of this disclosure provides a substrate processing apparatus including a conveying arm with an electrostatic chuck for attracting a semiconductor wafer, a substrate conveying device, and a method of controlling the substrate processing apparatus that make it possible to prevent the semiconductor wafer from sticking to the electrostatic chuck. In other words, an aspect of this disclosure makes it possible to easily remove a semiconductor wafer from a conveying arm and thereby makes it possible to prevent damage to a semiconductor device.

Another aspect of this disclosure provides a substrate processing apparatus, a substrate conveying device, and a method of controlling the substrate processing apparatus that make it possible to improve the throughput and reduce the power consumption of the substrate processing apparatus. In other words, an aspect of this disclosure makes it possible to reduce the period of time during which a voltage is applied to an electrostatic chuck of a conveying arm and thereby to reduce power consumption. Further, an aspect of this disclosure makes it unnecessary to apply a reverse voltage to an electrostatic chuck.

Non-limiting embodiments of the present invention are described below with reference to the accompanying drawings. Throughout the accompanying drawings, the same or corresponding reference numbers are assigned to the same or corresponding components, and overlapping descriptions of those components are omitted. Also, the drawings do not illustrate the relative sizes of components, and the actual dimensions of components may be determined by a person skilled in the art taking into account the non-limiting embodiments described below.

### First Embodiment

### <Substrate Processing Apparatus>

A first embodiment is described below. The first embodiment provides a substrate processing apparatus called a cluster tool that processes a substrate such as a semiconductor wafer and includes plural processing chambers and a transfer chamber connected to the processing chamber. A conveying arm provided in the transfer chamber includes an electrostatic chuck (ESC) for attracting a semiconductor wafer. The conveying arm moves the semiconductor wafer between the processing chambers and between the processing chambers and load lock chambers.

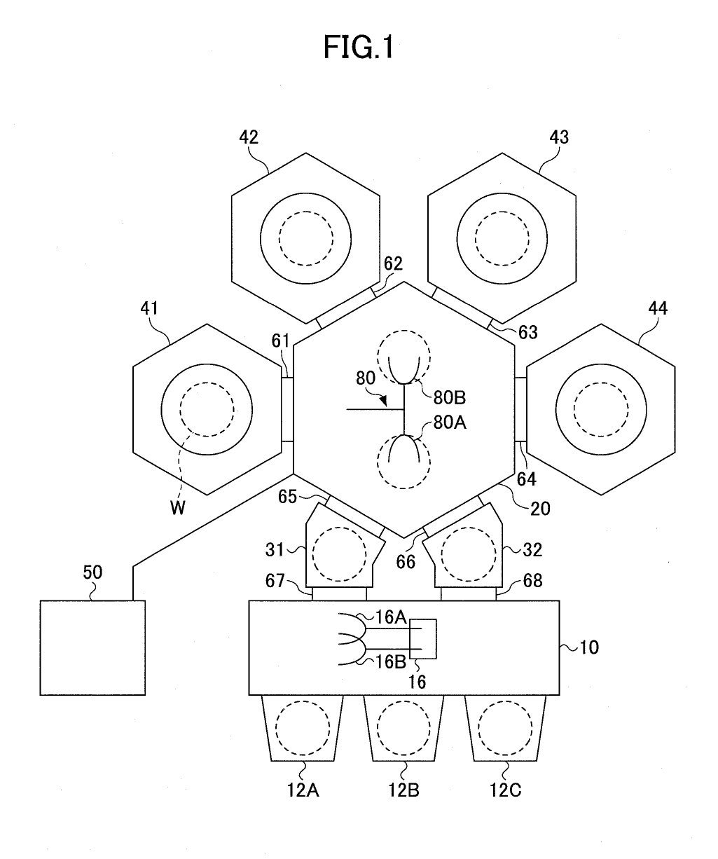

A substrate processing apparatus of the first embodiment is described below with reference to FIG. 1. The substrate processing apparatus of the first embodiment includes an atmospheric transfer chamber 10, a common transfer chamber 20, four single-wafer processing chambers 41, 42, 43, and 44, and a controller 50. The atmospheric transfer chamber 10 and the common transfer chamber 20 have functions of a substrate conveying device and may be called a substrate conveying device.

The common transfer chamber 20 has a substantially-hexagonal shape. The processing chambers 41, 42, 43, and 44 are connected to the common transfer chamber 20 at the corresponding sides of the substantially-hexagonal shape. Two load lock chambers 31 and 32 are provided between the common transfer chamber 20 and the atmospheric transfer chamber 10. Gate valves 61, 62, 63, and 64 are provided between the common transfer chamber 20 and the processing chambers 41, 42, 43, and 44. The gate valves 61, 62, 63, and 64 are configured to close the paths between the processing chambers 41, 42, 43, and 44 and the common transfer chamber 20. Gate valves 65 and 66 are provided between the common transfer chamber 20 and the load lock chambers 31 and 32. Also, gate valves 67 and 68 are provided between the load lock chambers 31 and 32 and the atmospheric transfer chamber 10. A vacuum pump (not shown) is connected to the common transfer chamber 20 to evacuate the common transfer chamber 20. Also, a vacuum pump (not shown) is connected to the load lock chambers 31 and 32 to separately evacuate the load lock chambers 31 and 32.

Three input ports 12A, 12B, and 120 are connected to a side of the atmospheric transfer chamber 10 that is opposite to the side of the atmospheric transfer chamber 10 to which the load lock chambers 31 and 32 are connected. The input ports 12A, 12B, and 12C receive cassettes each of which can house plural semiconductor wafers.

An input-side conveying mechanism 16 is provided in the atmospheric transfer chamber 10. The input-side conveying mechanism 16 includes two conveying arms 16A and 16B for holding semiconductor wafers W. The conveying arms 16A and 16B can perform extending, retracting, rotational, up-and-down, and linear movements to take out the semiconductor wafers W from the cassettes placed in the input ports 12A, 12B, and 12C, and move the semiconductor wafers W to the load lock chambers 31 and 32.

A conveying mechanism 80 including two conveying arms 80A and 80B for holding the semiconductor wafers W is provided in the common transfer chamber 20. The conveying arms 80A and 80B can perform extending, retracting, and rotational movements to move the semiconductor wafers W between the processing chambers 41, 42, 43, and 44, from the load lock chambers 31 and 32 to the processing chambers 41, 42, 43, and 44, and from the processing chambers 41, 42, 43, and 44 to the load lock chambers 31 and 32.

For example, the conveying arms 80A and 80B move the semiconductor wafers W from the load lock chambers 31 and 32 to the processing chambers 41, 42, 43, and 44 where the semiconductor wafers W are processed. In the processing chambers 41, 42, 43, and 44, different processes are performed on the semiconductor wafers W. Therefore, the semiconductor wafers W are moved between the processing chambers 41, 42, 43, and 44 by the conveying arms 80A and 80B. After the processes at the processing chambers 41, 42, 43, and 44 are completed, the semiconductor wafers W are moved from the processing chambers 41, 42, 43, and 44 to the load lock chambers 31 and 32 by the conveying arms 80A and 80B. Then, the processed semiconductor wafers W are moved from the load lock chambers 31 and 32 into the cassettes in the input ports 12A, 123, and 120 by the conveying arms 16A and 16B of the input-side conveying mechanism 16 provided in the atmospheric transfer chamber 10.

Here, the semiconductor wafers W are placed on the conveying arms 80A and 80B. When not being attracted by electrostatic chucks of the conveying arms 80A and 80B, the semiconductor wafers W are held on the conveying arms 80A and 802 by gravity.

Movement of the conveying arms 16A and 16B of the input-side conveying mechanism 16, movement of the conveying arms 80A and 80B of the conveying mechanism 80, processes on the semiconductor wafers W at the processing chambers 41, 42, 43, and 44, the gate valves 61, 62, 63, 64, 65, 66, 67, and 68, and evacuation of the load lock chambers 31 and 32 are controlled by the controller 50. The controller 50 also controls application of a voltage between electrodes 82 and 83 (described later) of each electrostatic chuck for attracting the semiconductor wafers W. The relationship between (the timing of) application of a voltage by the controller 50 and operations of the conveying arms 80A and 80B is described later.

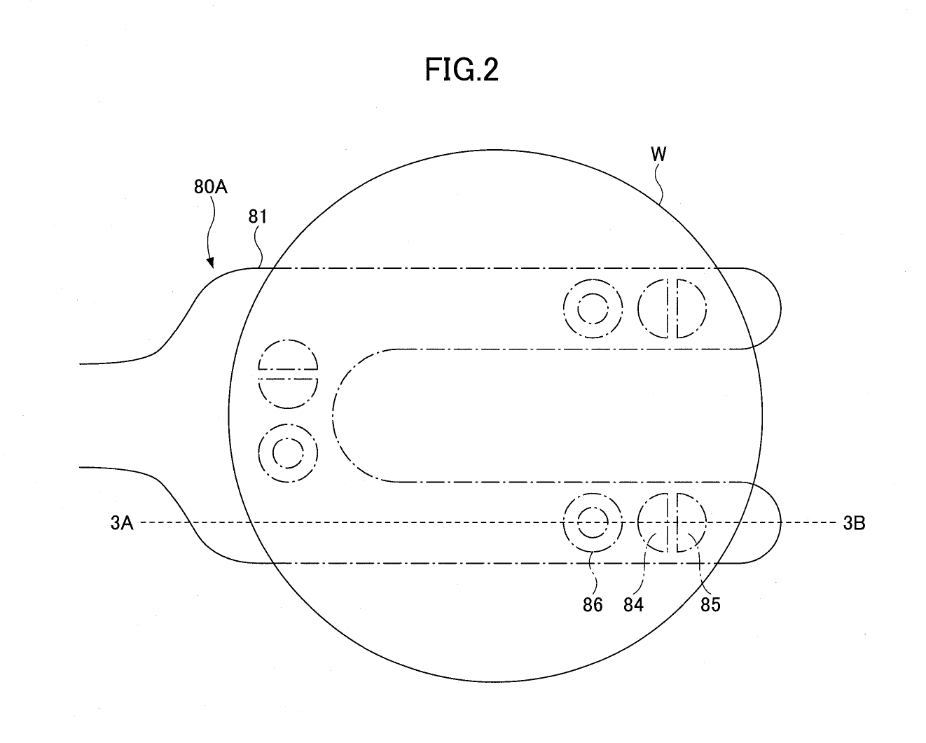

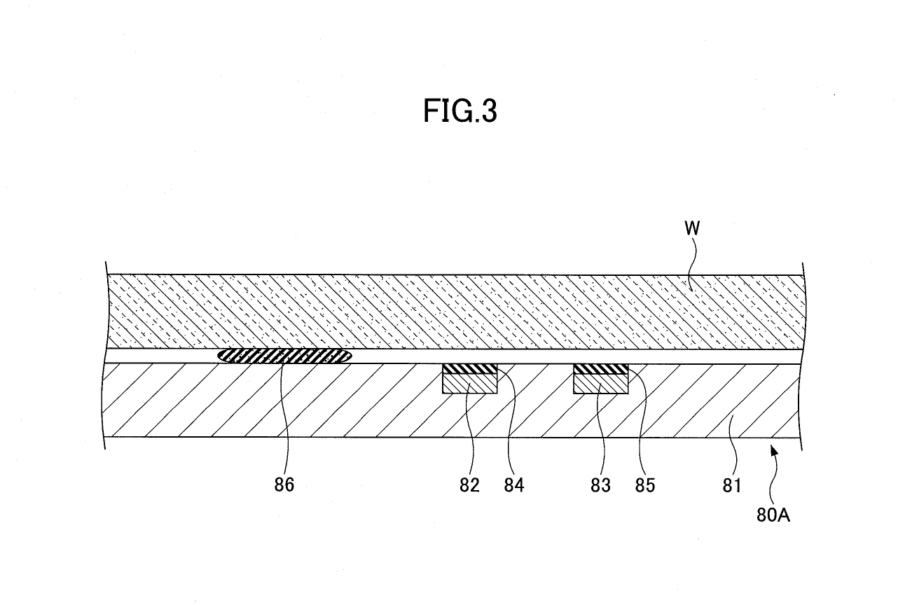

The conveying arm 80A of the present embodiment is described below with reference to FIGS. 2 and 3. FIG. 3 is an enlarged cross-sectional view of the conveying arm 80A taken along the dotted line 3A-3B of FIG. 2. The conveying arm 80A includes a main part 81 having a two-pronged or U-shaped tip on which the semiconductor wafer W is placed. The main part 81 may be made of, for example, a ceramic material such as aluminum oxide. Electrodes 82 and 83 made of a metallic material are formed on the U-shaped tip for electrostatic chucking. Insulating layers 84 and 85 made of, for example, polyimide are formed on the electrodes 82 and 83. O-rings 86 made of silicon rubber including a silicon compound are formed on an attracting side, which attracts the semiconductor wafer W, of the main part 81 of the conveying arm 80A so that the semiconductor wafer W does not directly contact the main part 81. The conveying arm 80B and the conveying arms 16A and 16B of the input-side conveying mechanism 16 may have substantially the same configuration.

### <Control Method of Substrate Processing Apparatus: Comparative Example>

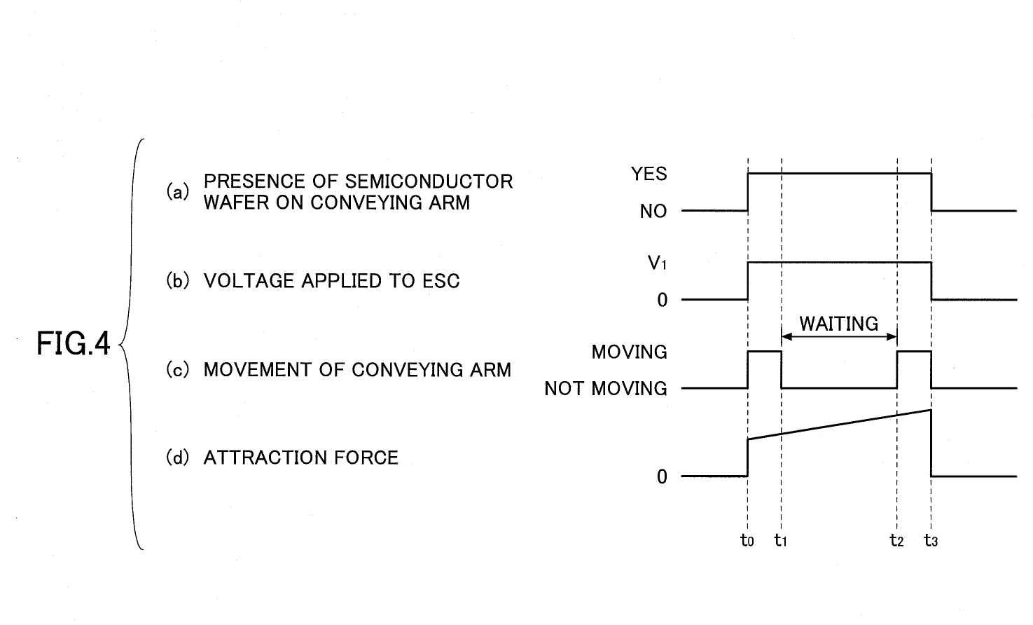

A method of controlling a substrate processing apparatus according to a comparative example is described below with reference to FIG. 4. FIG. 4 (a) indicates whether a semiconductor wafer is present on a conveying arm, FIG. 4 (b) indicates a voltage applied between electrodes of an electrostatic chuck of the conveying arm, FIG. 4 (c) indicates an operational status of the conveying arm, i.e., whether the conveying arm is moving, and FIG. 4 (d) indicates an attraction force between the electrostatic chuck of the conveying arm and the semiconductor wafer.

At time t0, the electrostatic chuck of the conveying arm attracts the semiconductor wafer. More specifically, a gate valve between a processing chamber where the semiconductor wafer is placed and the common transfer chamber is opened, the U-shaped tip of the conveying arm is placed under the semiconductor wafer, and then a voltage V1 is applied between the electrodes of the electrostatic chuck of the conveying arm to cause the electrostatic chuck to attract the semiconductor wafer. As a result, the semiconductor wafer is attracted to the conveying arm. Thus, at time t0, the semiconductor wafer is placed on the conveying arm and attracted to the conveying arm by the attraction force.

From time t0 to time t1, the conveying arm performs retracting and rotational movements. More specifically, the conveying arm retracts to move the semiconductor wafer placed on the U-shaped tip of the conveying arm from the processing chamber to the common transfer chamber. Then, the conveying arm rotates to move the semiconductor wafer to a position in the common transfer chamber near the next processing chamber where no semiconductor wafer is placed.

Before being moved to the next processing chamber, the semiconductor wafer is kept in the same position for a while. In other words, from time t1 to time t2, the conveying arm is stopped in the common transfer chamber. Even while the conveying arm is not moving, the voltage V1 is continuously applied between the electrodes of the electrostatic chuck and the attraction force increases.

From time t2 to time t3, the conveying arm performs an extending movement. More specifically, the conveying arm extends to move the semiconductor wafer placed on the U-shaped tip from the common transfer chamber to the next processing chamber.

Then, the conveying arm places the semiconductor wafer in a predetermined position in the next processing chamber. More specifically, at time t3, i.e., after the semiconductor wafer is moved to the predetermined position, the voltage applied between the electrodes of the electrostatic chuck is changed to 0 V to remove the attraction force of the electrostatic chuck and thereby place the semiconductor wafer in the predetermined position in the next processing chamber.

Through the above steps, the semiconductor wafer is moved between processing chambers. With the above method, however, since the voltage V1 is applied between the electrodes of the electrostatic chuck for a long period of time, the attraction force between the electrostatic chuck of the conveying arm and the semiconductor wafer gradually increases and the semiconductor wafer may stick to the electrostatic chuck. When such “sticking” occurs, it becomes difficult to detach the semiconductor wafer from the conveying arm.

Particularly, when O-rings positioned between the conveying arm and the semiconductor wafer are made of, for example, rubber including a silicon compound, the semiconductor wafer tends to stick to the electrostatic chuck via the O-rings and it becomes difficult to detach the semiconductor wafer from the conveying arm.

### <Control Method of Substrate Processing Apparatus: First Embodiment>

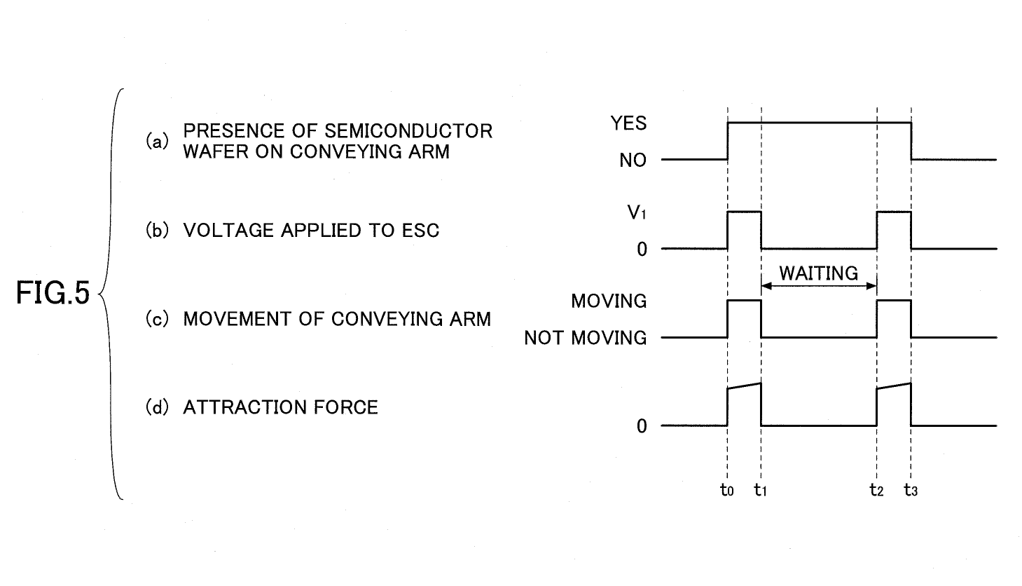

Next, a method of controlling the substrate processing apparatus of FIG. 1 according to the first embodiment is described with reference to FIG. 5. FIG. 5 (a) indicates whether the semiconductor wafer W is present on the conveying arm 80A, FIG. 5 (b) indicates a voltage applied between the electrodes 82 and 83 of the electrostatic chuck of the conveying arm 80A, FIG. 5 (c) indicates an operational status of the conveying arm 80A, i.e., whether the conveying arm 80A is moving, and FIG. 5 (d) indicates an attraction force between the electrostatic chuck of the conveying arm 80A and the semiconductor wafer.

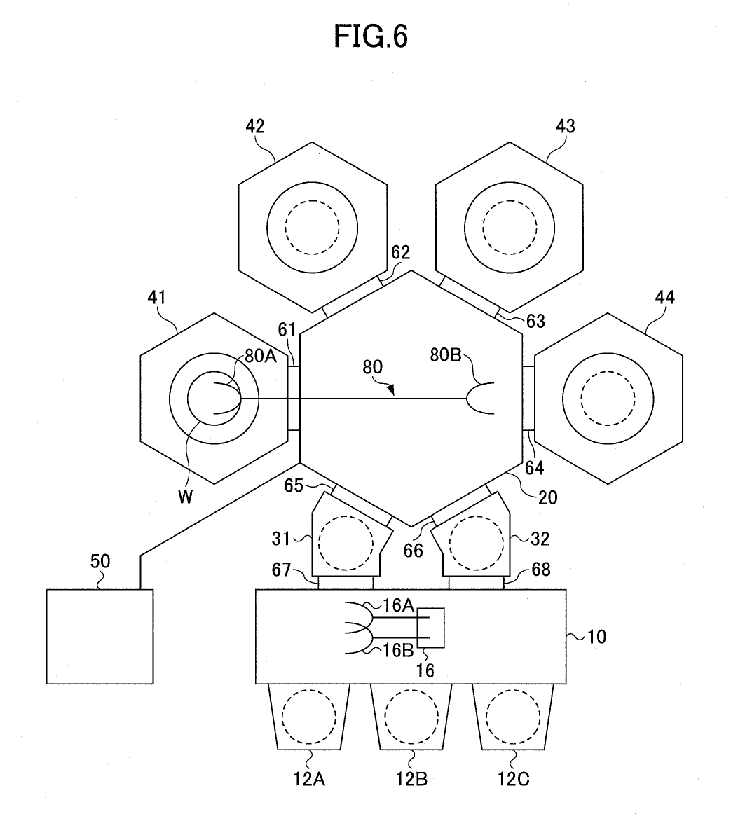

At time t0, the conveying arm 80A attracts the semiconductor wafer W via the electrostatic chuck. More specifically, as illustrated in FIG. 6, the gate valve 61 between the processing chamber 41 where the semiconductor wafer W is placed and the common transfer chamber 20 is opened, the U-shaped tip of the conveying arm 80A is placed under the semiconductor wafer W, and then a voltage V1 is applied between the electrodes 82 and 83 of the electrostatic chuck of the conveying arm 80A to cause the electrostatic chuck to attract the semiconductor wafer W. As a result, the semiconductor wafer W is attracted to the electrostatic chuck. Thus, at time t0, the semiconductor wafer W is attracted to the conveying arm 80A.

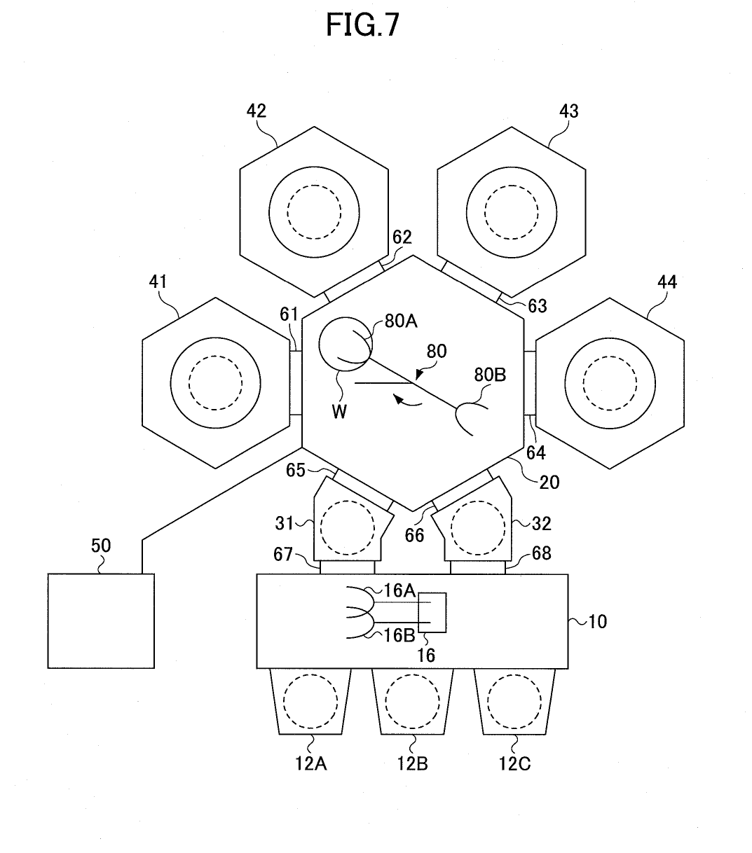

Next, from time t0 to time t1, the conveying arm 80A performs retracting and rotational (or swinging) movements (first moving step and rotating step). More specifically, the conveying arm 80A retracts to move the semiconductor wafer W placed on the U-shaped tip of the conveying arm 80A from the processing chamber 41 to the common transfer chamber 20. Then, as illustrated in FIG. 7, the conveying arm 80A rotates to move the semiconductor wafer W to a position in the common transfer chamber 20 near the next processing chamber 42 where no semiconductor wafer W is placed.

Before being moved to the processing chamber 42, the semiconductor wafer W is kept in the same position for a while. In other words, from time t1 to time t2, the conveying arm 80A is stopped in the common transfer chamber 20. While the conveying arm 80A is not moving, the voltage V1 applied between the electrodes 82 and 83 to generate the attraction force is stopped (removing step). More specifically, at time t1, the voltage applied between the electrodes 82 and 83 is changed from V1 to 0 V. As a result, the attraction force of the electrostatic chuck for attracting the semiconductor wafer W decreases during the time period between time t1 and time t2. Even when the voltage is changed to 0 V, the semiconductor wafer W is still held on the conveying arm 80A by gravity.

From time t2 to time t3, the conveying arm 80A performs an extending movement. More specifically, the conveying arm 80A extends to move the semiconductor wafer W placed on the U-shaped tip from the common transfer chamber 20 to the processing chamber 42. During this step, the voltage V1 is applied again between the electrodes 82 and 83 of the conveying arm 80A to attract the semiconductor wafer W (second moving step).

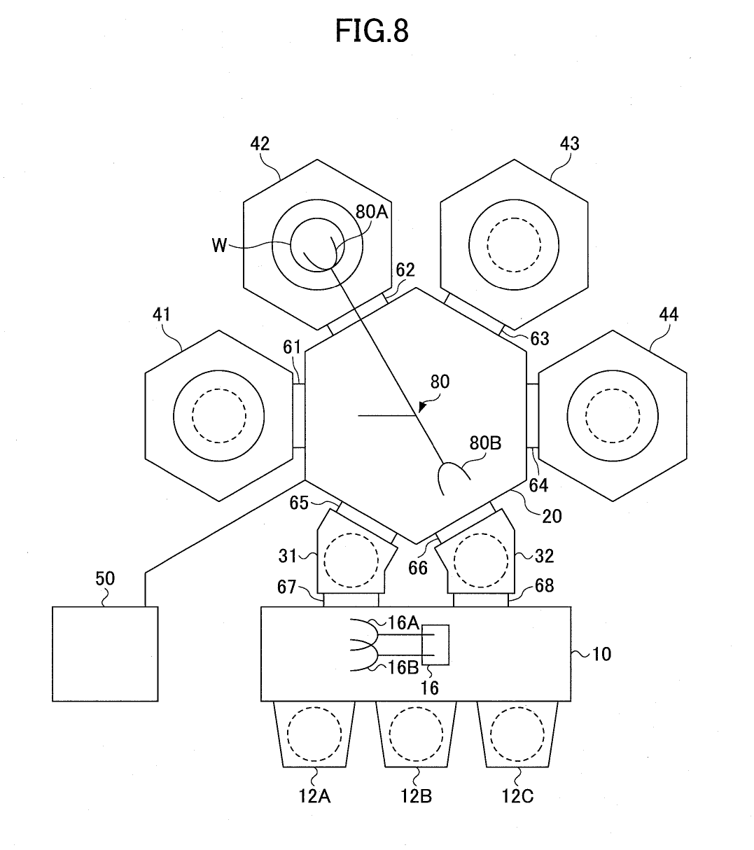

Then, the conveying arm 80A places the semiconductor wafer W in a predetermined position in the processing chamber 42. As illustrated in FIG. 8, at time t3, i.e., after the semiconductor wafer W is moved to the predetermined position, the voltage applied between the electrodes 82 and 83 of the electrostatic chuck is changed to 0 V to remove the attraction force of the electrostatic chuck and thereby place the semiconductor wafer W in the predetermined position in the processing chamber 42.

Through the above steps, the semiconductor wafer W is moved between processing chambers of the substrate processing apparatus. In the method of controlling the substrate processing apparatus of the first embodiment, a voltage of 0 V is applied between the electrodes 82 and 83 during time periods other than the time periods between time t0 and time t1 and between time t2 and time t3 where the conveying arm 80A is moving. In other words, the attraction force of the electrostatic chuck is removed during the time period between time t1 and time t2. This configuration makes it possible to prevent the semiconductor wafer W from sticking to the conveying arm 80A. That is, since the voltage V1 is applied between the electrodes 82 and 83 only while the conveying arm 80A is moving, the semiconductor wafer W is attracted to the conveying arm 80A only for a short period of time and therefore the attraction force does not increase much. Thus, the above configuration makes it possible to prevent the semiconductor wafer W from sticking to the conveying arm 80A.

Also, since the voltage V1 is not applied between the electrodes 82 and 83 while the conveying arm 80A is not moving, power is not consumed during the time period between time t1 and time t2. Thus, the above configuration also makes it possible to reduce power consumption and operation cost.

### <<Second Embodiment>>

Next, a second embodiment is described using the substrate processing apparatus of the first embodiment. In the second embodiment, a method of controlling the substrate processing apparatus includes a step of removing the attraction force caused by a residual charge on the electrostatic chuck.

### <Control Method of Substrate Processing Apparatus: Comparative Example>

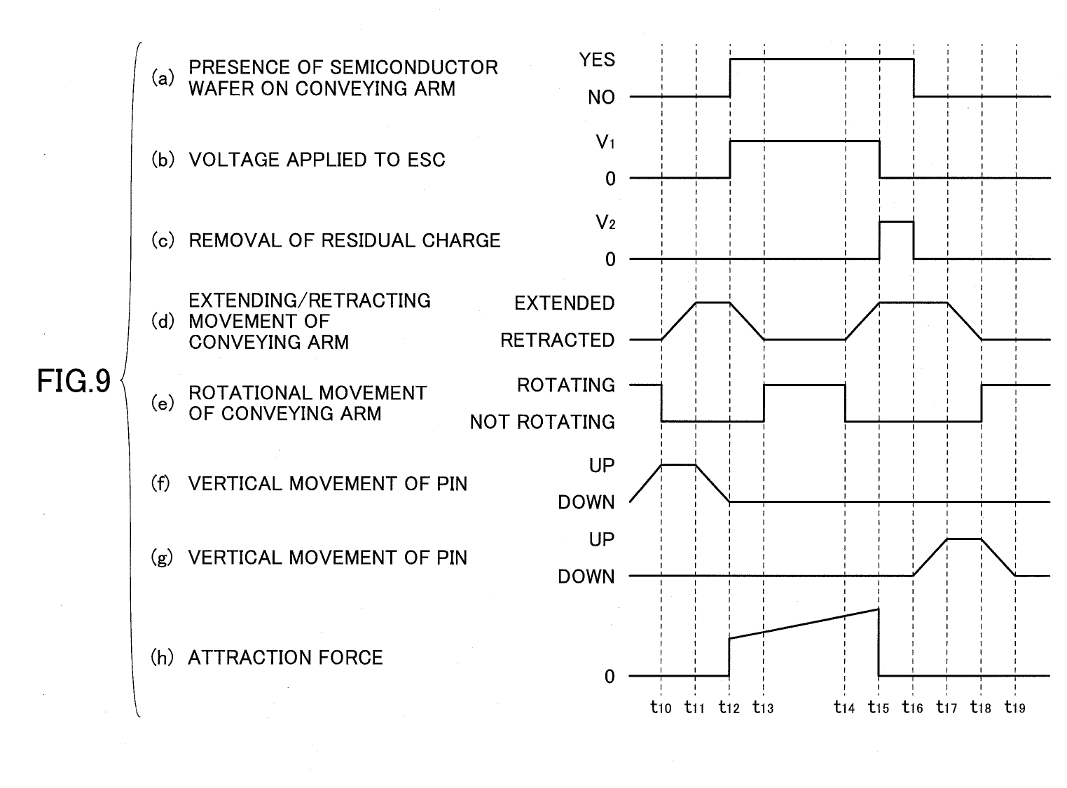

A method of controlling a substrate processing apparatus according to a comparative example is described below with reference to FIG. 9. This method includes a step of removing a residual charge on the electrostatic chuck. FIG. 9 (a) indicates whether a semiconductor wafer is present on the conveying arm; FIG. 9 (b) indicates a voltage applied between the electrodes of the electrostatic chuck to generate an attraction force; FIG. 9 (c) indicates a voltage applied between the electrodes of the electrostatic chuck to remove a residual charge on the electrostatic chuck; FIG. 9 (d) indicates a state of the conveying arm, i.e., whether the conveying arm is extended or retracted; FIG. 9 (e) indicates whether the conveying arm is rotating; FIG. 9 (f) indicates vertical movements of a pin used to move the semiconductor wafer up and down in a processing chamber (hereafter called “processing chamber A”) where the semiconductor wafer is already placed; FIG. 9 (g) indicates vertical movements of a pin used to move the semiconductor wafer up and down in a processing chamber (hereafter called “processing chamber B”) where the semiconductor wafer is placed next; and FIG. 9 (h) indicates the attraction force between the electrostatic chuck of the conveying arm and the semiconductor wafer.

First, from time t10 to time t11, the conveying arm extends toward the processing chamber A where the semiconductor wafer is already placed. At this stage, the semiconductor wafer is not placed on the conveying arm and no voltage is applied between the electrodes of the electrostatic chuck of the conveying arm. In the processing chamber A, the pin has been raised to lift the semiconductor wafer and the semiconductor wafer is at a raised position. Accordingly, at time t11, the conveying arm is in an extended state and the U-shaped tip of the conveying arm is positioned under the semiconductor wafer in the processing chamber A.

From time t11 to time t12, the pin in the processing chamber A is lowered to place the semiconductor wafer on the U-shaped tip of the conveying arm.

From time t12 to time t13, the voltage V1 is applied between the electrodes of the electrostatic chuck of the conveying arm to generate an attraction force and thereby to attract the semiconductor wafer to the electrostatic chuck, and the conveying arm retracts to move the semiconductor wafer from the processing chamber A to the common transfer chamber.

From time t13 to time t14, the conveying arm rotates to move the semiconductor wafer to a position near the processing chamber B.

From time t14 to time t15, the conveying arm extends toward the processing chamber B to move the semiconductor wafer into the processing chamber B.

At time t15, the voltage V1 being applied between the electrodes of the electrostatic chuck of the conveying arm is turned off. Then, from time t15 to time t16, a reverse voltage V2, which is opposite to the voltage V1 applied from time t12 to time t15, is applied between the electrodes to remove a charge remaining on the semiconductor wafer and the electrostatic chuck and to thereby effectively remove the attraction force.

From time t16 to time t17, the pin in the processing chamber B is raised to lift the semiconductor wafer on the conveying arm.

From time t17 to time t18, the conveying arm retracts to move the U-shaped tip from the processing chamber B to the common transfer chamber.

Then, from time t18 to time t19, the pin in the processing chamber B is lowered to place the semiconductor wafer in a predetermined position in the processing chamber B.

Through the above steps, the semiconductor wafer is moved from the processing chamber A to the processing chamber B.

### <Control Method of Substrate Processing Apparatus: Second Embodiment>

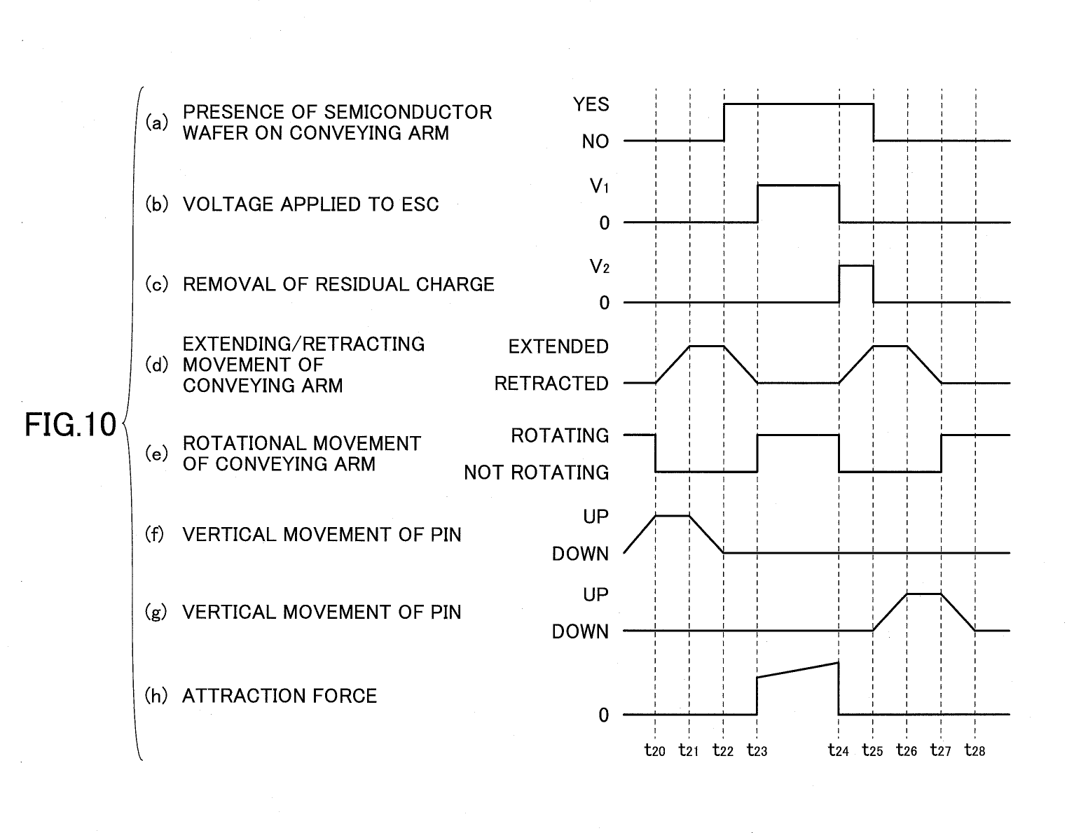

Next, a method of controlling the substrate processing apparatus (FIG. 1) according to the second embodiment is described with reference to FIG. 10. FIG. 10 (a) indicates whether the semiconductor wafer W is present on the conveying arm 80A; FIG. 10 (b) indicates a voltage applied between the electrodes 82 and 83 of the electrostatic chuck to generate an attraction force; FIG. 10 (c) indicates a voltage applied between the electrodes 82 and 83 of the electrostatic chuck to remove a residual charge on the electrostatic chuck; FIG. 10 (d) indicates a state of the conveying arm 80A, i.e., whether the conveying arm 80A is extended or retracted; FIG. 10 (e) indicates whether the conveying arm 80A is rotating; FIG. 10 (f) indicates vertical movements of a pin (not shown) used to move the semiconductor wafer W up and down in the processing chamber 41; FIG. 10 (g) indicates vertical movements of a pin (not shown) used to move the semiconductor wafer W up and down in the processing chamber 42; and FIG. 10 (h) indicates the attraction force between the electrostatic chuck of the conveying arm 80A and the semiconductor wafer W. In the substrate processing apparatus control method of the second embodiment, the semiconductor wafer W is attracted by the electrostatic chuck only while the conveying arm 80A is rotating. When the conveying arm 80A rotates, centrifugal force is applied to the semiconductor wafer W. That is, the force applied to the semiconductor wafer W when the conveying arm 80A is rotating is greater than that when the conveying arm 80A is extending or retracting. Therefore, during the extending and retracting movements of the conveying arm, it is possible to hold the semiconductor wafer W on the conveying arm 80A without using the attraction force of the electrostatic chuck. Meanwhile, during the rotational movement of the conveying arm, it is necessary to attract the semiconductor wafer W by the electrostatic chuck to hold the semiconductor wafer W on the conveying arm 80A.

First, from time t20 to time t21, the conveying arm 80A extends toward the processing chamber 41. At this stage, the semiconductor wafer W is not placed on the conveying arm 80A and the voltage being applied between the electrodes 82 and 83 of the electrostatic chuck of the conveying arm 80A is 0 V. In the processing chamber 41, the pin (not shown) has been raised to lift the semiconductor wafer W and the semiconductor wafer W is at a raised position. Accordingly, at time t21, the conveying arm 80A is in an extended state and the U-shaped tip of the conveying arm 80A is positioned under the semiconductor wafer W in the processing chamber 41 as illustrated in FIG. 6.

From time t21 to time t22, the pin (not shown) in the processing chamber 41 is lowered to place the semiconductor wafer W on the U-shaped tip of the conveying arm 80A.

From time t22 to time t23, the conveying arm 80A retracts to move the semiconductor wafer W from the processing chamber 41 to the common transfer chamber 20 (first moving step).

From time t23 to time t24, the voltage V1 is applied between the electrodes 82 and 83 of the electrostatic chuck of the conveying arm 80A to generate an attraction force and thereby to attract the semiconductor wafer W to the electrostatic chuck. After the voltage V1 is applied between the electrodes 82 and 83 of the electrostatic chuck, the conveying arm 80A rotates to move the semiconductor wafer W to a position near the processing chamber 42 as illustrated in FIG. 7 (rotating step).

At time t24, the voltage V1 being applied between the electrodes 82 and 83 of the electrostatic chuck of the conveying arm 80A is turned off (removing step), and a voltage of 0 V is applied between the electrodes 82 and 83. From time t24 to time t25, a reverse voltage V2, which is opposite to the voltage V1 applied from time t23 to time t24, is applied between the electrodes 82 and 83 to effectively remove the attraction force of the electrostatic chuck of the conveying arm 80A. At the same time, the conveying arm 80A extends toward the processing chamber 42 to move the semiconductor wafer W into the processing chamber 42 as illustrated in FIG. 8 (second moving step). At this stage, although the attraction force is removed, the semiconductor wafer W is still held on the conveying arm 80A by gravity.

From time t25 to time t26, the pin (not shown) in the processing chamber 42 is raised to lift the semiconductor wafer W on the conveying arm 80A.

From time t26 to time t27, the conveying arm 80A retracts to move the U-shaped tip from the processing chamber 42 to the common transfer chamber 20.

Then, from time t27 to time t28, the pin (not shown) in the processing chamber 42 is lowered to place the semiconductor wafer W in a predetermined position in the processing chamber 42.

Through the above steps, the semiconductor wafer W is moved from the processing chamber 41 to the processing chamber 42.

In the second embodiment, the extending movement of the conveying arm 80A and the application of the reverse voltage V2 for effectively removing the attraction force of the electrostatic chuck are performed at the same time. This method makes it possible to reduce the time necessary to move the semiconductor wafer W between processing chambers and thereby makes it possible to improve throughput. More specifically, the second embodiment makes it possible to reduce the time period between time t14 and time t16 in the control method of the comparative example (FIG. 9) to the time period between time t24 and time t25, and thereby makes it possible to improve the throughput. Also, while the semiconductor wafer is attracted by the electrostatic chuck for a time period between time t12 and time t15 in the control method of the comparative example (FIG. 9), the semiconductor wafer W is attracted by the electrostatic chuck for a shorter time period between time t23 and time t24 in the control method of the second embodiment. Thus, the second embodiment makes it possible to prevent the semiconductor wafer W from sticking to the electrostatic chuck and also to reduce power consumption. Here, it is assumed that the time period between time t10 and time t14 in FIG. 9 is the same as the time period between time t20 and time t24 in FIG. 10, and the time period between time t16 and time t19 in FIG. 9 is the same as the time period between time t25 and time t28 in FIG. 10.

### <<Third Embodiment>>

Next, a third embodiment is described using the substrate processing apparatus of the first embodiment. In the third embodiment, unlike the second embodiment, a method of controlling the substrate processing apparatus does not include the step of applying the reverse voltage to remove the attraction force of the electrostatic chuck. Also in the third embodiment, it is assumed that there is a wait period before the semiconductor wafer is moved into the next processing chamber.

### <Control Method of Substrate Processing Apparatus: Comparative Example>

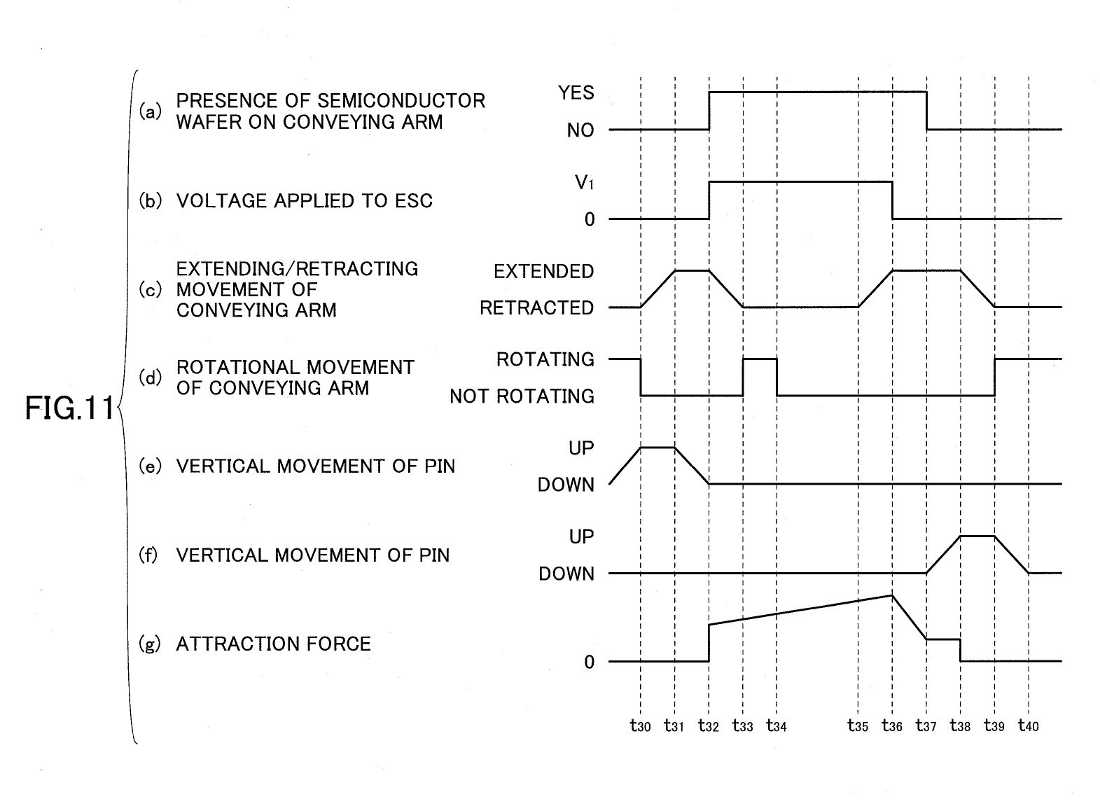

A method of controlling a substrate processing apparatus according to a comparative example is described below with reference to FIG. 11. FIG. 11 (a) indicates whether a semiconductor wafer is present on the conveying arm; FIG. 11 (b) indicates a voltage applied between the electrodes of the electrostatic chuck; FIG. 11 (c) indicates a state of the conveying arm, i.e., whether the conveying arm is extended or retracted; FIG. 11 (d) indicates whether the conveying arm is rotating; FIG. 11 (e) indicates vertical movements of a pin used to move the semiconductor wafer up and down in a processing chamber (hereafter called “processing chamber A”) where the semiconductor wafer is already placed; FIG. 11 (f) indicates vertical movements of a pin used to move the semiconductor wafer up and down in a processing chamber (hereafter called “processing chamber B”) where the semiconductor wafer is placed next; and FIG. 11 (g) indicates the attraction force between the electrostatic chuck of the conveying arm and the semiconductor wafer.

First, from time t30 to time t31, the conveying arm extends toward the processing chamber A where the semiconductor wafer is already placed. At this stage, the semiconductor wafer W is not placed on the conveying arm and the voltage being applied between the electrodes of the electrostatic chuck of the conveying arm is 0 V. In the processing chamber A, the pin has been raised to lift the semiconductor wafer and the semiconductor wafer is at a raised position. Accordingly, at time t31, the conveying arm is in an extended state and the U-shaped tip of the conveying arm is positioned under the semiconductor wafer in the processing chamber A.

From time t31 to time t32, the pin in the processing chamber A is lowered to place the semiconductor wafer on the U-shaped tip of the conveying arm.

From time t32 to time t33, the voltage V1 is applied between the electrodes of the electrostatic chuck of the conveying arm to generate an attraction force and thereby to attract the semiconductor wafer to the electrostatic chuck, and the conveying arm retracts to move the semiconductor wafer from the processing chamber A to the common transfer chamber.

From time t33 to time t34, the conveying arm rotates to move the semiconductor wafer to a position near the processing chamber B.

From time t34 to time t35, the semiconductor wafer is kept in the same position in the common transfer chamber until the processing chamber B becomes ready. In other words, the conveying arm is stopped from time t34 to time t35. Even while the conveying arm is not moving, the voltage V1 is continuously applied between the electrodes of the electrostatic chuck and the attraction force gradually increases.

From time t35 to time t36, the conveying arm extends toward the processing chamber B to move the semiconductor wafer into the processing chamber B.

At time t36, the voltage being applied between the electrodes of the electrostatic chuck of the conveying arm is changed from V1 to 0 V. Here, since the voltage V1 has been applied between the electrodes of the electrostatic chuck for a long period of time before the voltage is changed to 0V, the attraction force of the electrostatic chuck is at a high level. Therefore, even when the voltage is changed to 0 V at time t36, the attraction force does not immediately fall to zero, but gradually decreases. For this reason, no operation is performed until the attraction force becomes less than or equal to a predetermined value at time t37.

From time t37 to time t38, the pin in the processing chamber B is raised to lift the semiconductor wafer on the conveying arm.

From time t38 to time t39, the conveying arm retracts to move the U-shaped tip from the processing chamber B to the common transfer chamber.

Then, from time t39 to time t40, the pin in the processing chamber B is lowered to place the semiconductor wafer in a predetermined position in the processing chamber B.

Through the above steps, the semiconductor wafer is moved from the processing chamber A to the processing chamber B.

### <Control Method of Substrate Processing Apparatus: Third Embodiment>

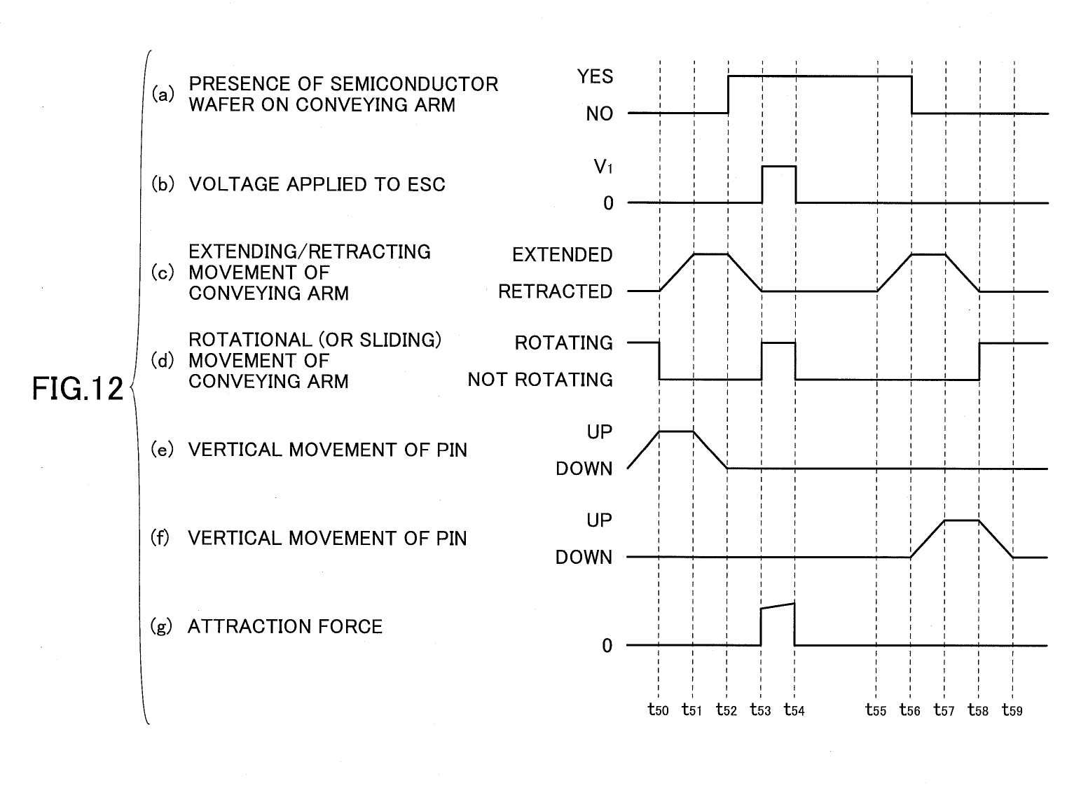

Next, a method of controlling the substrate processing apparatus (FIG. 1) according to the third embodiment is described with reference to FIG. 12. FIG. 12 (a) indicates whether the semiconductor wafer W is present on the conveying arm 80A; FIG. 12 (b) indicates a voltage applied between the electrodes 82 and 83 of the electrostatic chuck; FIG. 12 (c) indicates a state of the conveying arm 80A, i.e., whether the conveying arm 80A is extended or retracted; FIG. 12 (d) indicates whether the conveying arm 80A is rotating; FIG. 12 (e) indicates vertical movements of a pin (not shown) used to move the semiconductor wafer W up and down in the processing chamber 41; FIG. 12 (f) indicates vertical movements of a pin (not shown) used to move the semiconductor wafer W up and down in the processing chamber 42; and FIG. 10 (g) indicates the attraction force between the electrostatic chuck of the conveying arm 80A and the semiconductor wafer W.

First, from time t50 to time t51, the conveying arm 80A extends toward the processing chamber 41 where the semiconductor wafer W is already placed. At this stage, the semiconductor wafer W is not placed on the conveying arm 80A and the voltage being applied between the electrodes 82 and 83 of the electrostatic chuck of the conveying arm 80A is 0 V. In the processing chamber 41, the pin has been raised to lift the semiconductor wafer W and the semiconductor wafer W is at a raised position. Accordingly, at time t51, the conveying arm 80A is in an extended state and the U-shaped tip of the conveying arm 80A is positioned under the semiconductor wafer W in the processing chamber 41.

From time t51 to time t52, the pin (not shown) in the processing chamber 41 is lowered to place the semiconductor wafer W on the U-shaped tip of the conveying arm 80A.

From time t52 to time t53, the conveying arm 80A retracts to move the semiconductor wafer W from the processing chamber 41 to the common transfer chamber 20 (first moving step).

From time t53 to time t54, the voltage V1 is applied between the electrodes 82 and 83 of the electrostatic chuck of the conveying arm 80A to generate an attraction force and thereby to attract the semiconductor wafer W to the electrostatic chuck, and the conveying arm 80A rotates to move the semiconductor wafer W to a position near the processing chamber 42 as illustrated in FIG. 7 (rotating step).

From time t54 to time t55, the semiconductor wafer W is kept in the same position in the common transfer chamber 20 until preparation for moving the semiconductor wafer W into the processing chamber 42 is completed. In other words, the conveying arm 80A is stopped from time t54 to time t55. Also, at time t54, the voltage V1 applied between the electrodes 82 and 83 to generate the attraction force is stopped (removing step). In other words, the voltage being applied between the electrodes 82 and 83 is changed to 0 V and the attraction force of the electrostatic chuck is removed. At this stage, although the attraction force is removed, the semiconductor wafer W is still held on the conveying arm 80A by gravity.

From time t55 to time t56, the conveying arm 80A extends toward the processing chamber 42 to move the semiconductor wafer W into the processing chamber 42 as illustrated in FIG. 8 (second moving step).

From time t56 to time t57, the pin (not shown) in the processing chamber 42 is raised to lift the semiconductor wafer W on the conveying arm 80A.

From time t57 to time t58, the conveying arm 80A retracts to move the U-shaped tip from the processing chamber 42 to the common transfer chamber 20.

Then, from time t58 to time t59, the pin (not shown) in the processing chamber 42 is lowered to place the semiconductor wafer W in a predetermined position in the processing chamber 42.

Through the above steps, the semiconductor wafer W is moved from the processing chamber 41 to the processing chamber 42.

In the third embodiment, the voltage V1 is applied between the electrodes 82 and 83 of the electrostatic chuck of the conveying arm 80A to generate an attraction force only while the conveying arm 80A is rotating, i.e., for the time period between time t53 and time t54. This method makes it possible to prevent “sticking” and eliminates the need to wait until the attraction force decreases (i.e., the time period between time t36 and time t37 in FIG. 11 is not necessary). Thus, the third embodiment makes it possible to improve the throughput of the substrate processing apparatus and also makes it possible to reduce power consumption. Here, it is assumed that the time period between time t30 and time t36 in FIG. 11 is the same as the time period between time t50 and time t56 in FIG. 12, and the time period between time t37 and time t40 in FIG. 11 is the same as the time period between time t56 and time t59 in FIG. 12.

### <<Fourth Embodiment>>

Next, a fourth embodiment is described using the substrate processing apparatus of the first embodiment. The fourth embodiment is different from the third embodiment in that the semiconductor wafer W is attracted by the electrostatic chuck also during the extending and retracting movements of the conveying arm 80A.

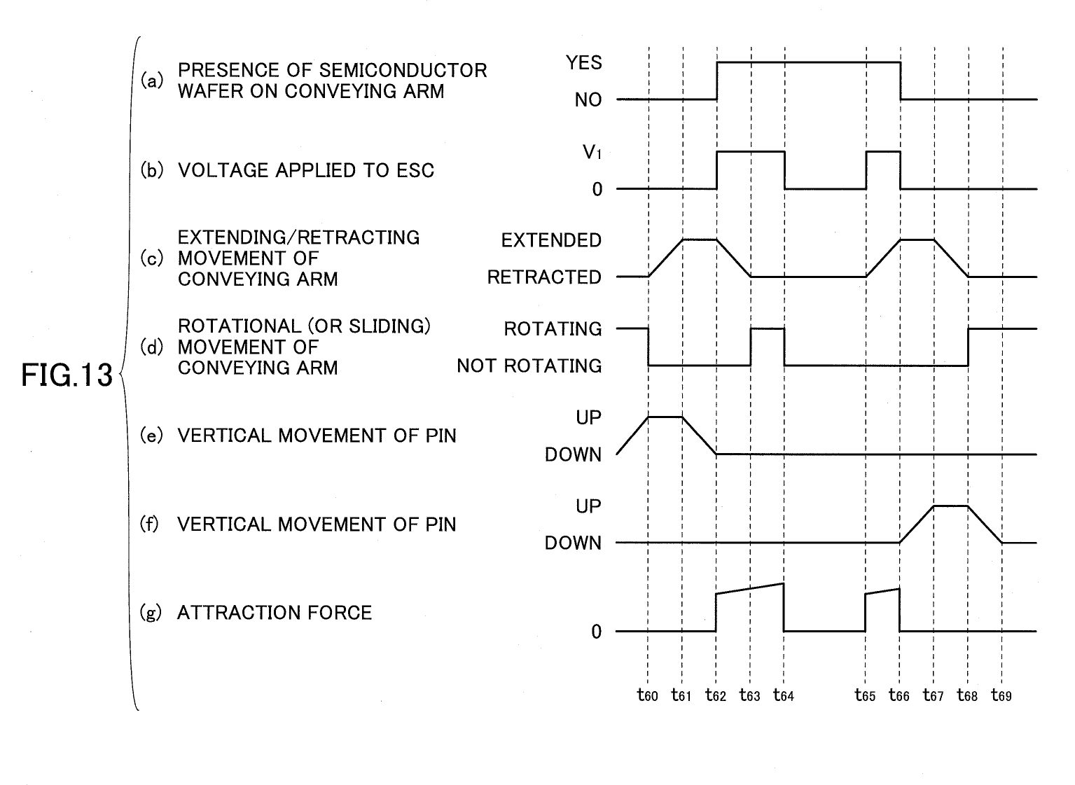

A method of controlling the substrate processing apparatus (FIG. 1) according to the fourth embodiment is described below with reference to FIG. 13. FIG. 13 (a) indicates whether the semiconductor wafer W is present on the conveying arm 80A; FIG. 13 (b) indicates a voltage applied between the electrodes 82 and 83 of the electrostatic chuck; FIG. 13 (c) indicates a state of the conveying arm 80A, i.e., whether the conveying arm 80A is extended or retracted; FIG. 13 (d) indicates whether the conveying arm 80A is rotating; FIG. 13 (e) indicates vertical movements of a pin (not shown) used to move the semiconductor wafer W up and down in the processing chamber 41; FIG. 13 (f) indicates vertical movements of a pin (not shown) used to move the semiconductor wafer W up and down in the processing chamber 42; and FIG. 13 (g) indicates the attraction force between the electrostatic chuck of the conveying arm 80A and the semiconductor wafer W.

First, from time t60 to time t61, the conveying arm 80A extends toward the processing chamber 41 where the semiconductor wafer W is already placed. At this stage, the semiconductor wafer W is not placed on the conveying arm 80A and no voltage is applied between the electrodes 82 and 83 of the electrostatic chuck of the conveying arm 80A. In the processing chamber 41, the pin has been raised to lift the semiconductor wafer W and the semiconductor wafer W is at a raised position. Accordingly, at time t61, the conveying arm 80A is in an extended state and the U-shaped tip of the conveying arm 80A is positioned under the semiconductor wafer W in the processing chamber 41.

From time t61 to time t62, the pin (not shown) in the processing chamber 41 is lowered to place the semiconductor wafer W on the U-shaped tip of the conveying arm 80A.

At time t62, the voltage V1 is applied between the electrodes 82 and 83 of the electrostatic chuck of the conveying arm 80A to generate an attraction force and thereby to attract the semiconductor wafer W to the electrostatic chuck. From time t62 to time t63, the conveying arm 80A retracts to move the semiconductor wafer W from the processing chamber 41 to the common transfer chamber 20 (first moving step).

From time t63 to time t64, the conveying arm 80A rotates to move the semiconductor wafer W to a position near the processing chamber 42 as illustrated in FIG. 7 (rotating step).

From time t64 to time t65, the semiconductor wafer W is kept in the same position in the common transfer chamber 20 until preparation for moving the semiconductor wafer W into the processing chamber 42 is completed. In other words, the conveying arm 80A is stopped from time t64 to time t65. Meanwhile, at time t64, the voltage V1 being applied between the electrodes 82 and 83 to generate the attraction force is stopped (removing step). In other words, the voltage being applied between the electrodes 82 and 83 is changed to 0 V, and the attraction force of the electrostatic chuck is removed during a time period between time t64 and time t65. Even when the attraction force is removed, the semiconductor wafer W is still held on the conveying arm 80A by gravity.

At time t65, the voltage V1 is applied again between the electrodes 82 and 83 of the electrostatic chuck of the conveying arm 80A to attract the semiconductor wafer W to the electrostatic chuck. From time t65 to time t66, the conveying arm 80A extends toward the processing chamber 42 to move the semiconductor wafer W into the processing chamber 42 as illustrated in FIG. 8 (second moving step). At time t66, the voltage being applied between the electrodes 82 and 83 is changed to 0 V to remove the attraction force of the electrostatic chuck.

From time t66 to time t67, the pin (not shown) in the processing chamber 42 is raised to lift the semiconductor wafer W on the conveying arm 80A.

From time t67 to time t68, the conveying arm 80A retracts to move the U-shaped tip from the processing chamber 42 to the common transfer chamber 20.

Then, from time t68 to time t69, the pin (not shown) in the processing chamber 42 is lowered to place the semiconductor wafer W in a predetermined position in the processing chamber 42.

Through the above steps, the semiconductor wafer W is moved from the processing chamber 41 to the processing chamber 42.

In the fourth embodiment, the voltage V1 is applied between the electrodes 82 and 83 of the electrostatic chuck of the conveying arm 80A to generate an attraction force only while the conveying arm 80A is retracting, rotating, and extending, i.e., during the time periods between time t62 and time t64 and between time t65 and time t66. Thus, the voltage V1 is applied between the electrodes 82 and 83 only for a short period of time. This method makes it possible to prevent “sticking”, to improve the throughput, and to reduce power consumption. Here, it is assumed that the time period between time t30 and time t36 in FIG. 11 is the same as the time period between time t60 and time t66 in FIG. 13, and the time period between time t37 and time t40 in FIG. 11 is the same as the time period between time t66 and time t69 in FIG. 13.

The fourth embodiment is described using a process of moving the semiconductor wafer W from the processing chamber 41 to the processing chamber 42. However, the fourth embodiment may also be applied to a process of moving the semiconductor wafer W between any other combination of the processing chambers 41, 42, 43, and 44 and between the load lock chambers 31 and 32 and the processing chambers 41, 42, 43, and 44. Also, the fourth embodiment may be applied to the conveying arm 808 and the conveying arms 16A and 16B of the input-side conveying mechanism 16.

### <<Fifth Embodiment>>

Next, a fifth embodiment is described using the substrate processing apparatus of the first embodiment. The fifth embodiment is different from the third embodiment in that no voltage is applied between the electrodes 82 and 83 of the electrostatic chuck during a wait period where the conveying arm 80A holding the semiconductor wafer W is stopped and during the retracting and extending movements of the conveying arm 80A, the electrodes 82 and 83 are opened (or disconnected) during the wait period, and a voltage of 0 V is applied between the electrodes 82 and 83 of the electrostatic chuck before the semiconductor wafer W is detached from the conveying arm 80A.

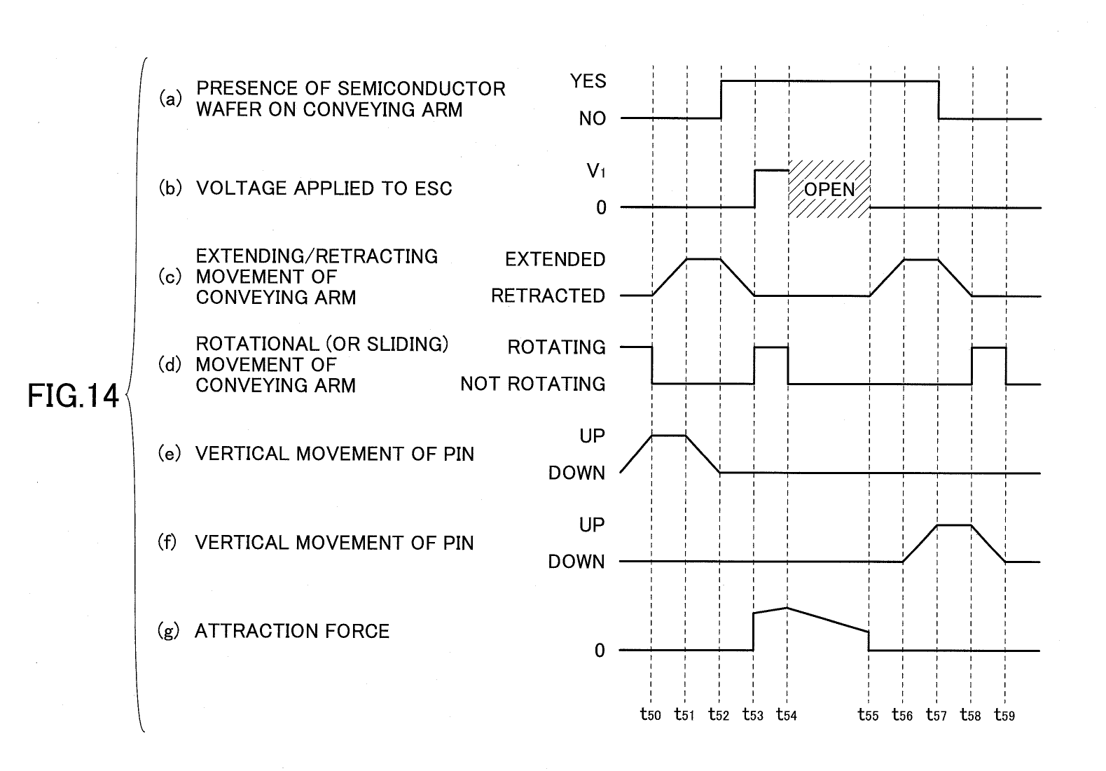

FIG. 14 (a) indicates whether the semiconductor wafer W is present on the conveying arm 80A; FIG. 14 (b) indicates a voltage applied between the electrodes 82 and 83 of the electrostatic chuck; FIG. 14 (c) indicates a state of the conveying arm 80A, i.e., whether the conveying arm 80A is extended or retracted; FIG. 14 (d) indicates whether the conveying arm 80A is rotating; FIG. 14 (e) indicates vertical movements of a pin (not shown) used to move the semiconductor wafer W up and down in the processing chamber 41; FIG. 14 (f) indicates vertical movements of a pin (not shown) used to move the semiconductor wafer W up and down in the processing chamber 42; and FIG. 14 (g) indicates the attraction force between the electrostatic chuck of the conveying arm 80A and the semiconductor wafer W.

First, from time t50 to time t51, the conveying arm 80A extends toward the processing chamber 41 where the semiconductor wafer W is already placed. At this stage, the semiconductor wafer W is not placed on the conveying arm 80A and the voltage being applied between the electrodes 82 and 83 of the electrostatic chuck of the conveying arm 80A is 0 V. In the processing chamber 41, the pin (not shown) has been raised to lift the semiconductor wafer W and the semiconductor wafer W is at a raised position. Accordingly, at time t51, the conveying arm 80A is in an extended state and the U-shaped tip of the conveying arm 80A is positioned under the semiconductor wafer W that is lifted by the pin in the processing chamber 41.

From time t51 to time t52, the pin (not shown) in the processing chamber 41 is lowered to place the semiconductor wafer W on the U-shaped tip of the conveying arm 80A.

From time t52 to time t53, the conveying arm 80A retracts to move the semiconductor wafer W from the processing chamber 41 to the common transfer chamber 20 (first moving step).

From time t53 to time t54, the voltage V1 is applied between the electrodes 82 and 83 of the electrostatic chuck of the conveying arm 80A to generate an attraction force and thereby to attract the semiconductor wafer W to the electrostatic chuck. During the same time period, the conveying arm 80A rotates to move the semiconductor wafer W to a position near the processing chamber 42 as illustrated in FIG. 7 (rotating step).

From time t54 to time t55, the semiconductor wafer W is kept in the same position in the common transfer chamber 20 until preparation for moving the semiconductor wafer W into the processing chamber 42 is completed. In other words, the conveying arm 80A is stopped from time t54 to time t55. Meanwhile, at time t54, the voltage V1 being applied between the electrodes 82 and 83 to generate the attraction force is stopped, and the electrodes 82 and 83 are opened (removing step). As a result, an electric charge (residual charge) accumulated on the electrodes 82 and 83 and the semiconductor wafer W is substantially maintained or decreases due to leakage. In other words, the attraction force of the electrostatic chuck is maintained at substantially the same level as that before the electrodes 82 and 83 are opened, or gradually decreases unlike the case where a voltage of 0 V is applied between the electrodes 82 and 83. When the attraction force is maintained by the residual charge, the semiconductor wafer W continues to be attracted to the conveying arm 80A. Even when the attraction force is removed after a while, the semiconductor wafer W is still held on the conveying arm 80A by gravity.

From time t55 to time t56, the conveying arm 80A extends toward the processing chamber 42 to move the semiconductor wafer W into the processing chamber 42 as illustrated in FIG. 8 (second moving step). Meanwhile, at time t55, a voltage of 0 V is applied between the electrodes 82 and 83. As a result, the residual charge on the electrodes 82 and 83 and the semiconductor wafer W is removed and the attraction force of the electrostatic chuck is removed. Still, however, the semiconductor wafer W is held on the conveying arm 80A by gravity.

From time t56 to time t57, the pin (not shown) in the processing chamber 42 is raised to lift the semiconductor wafer W on the conveying arm 80A.

From time t57 to time t58, the conveying arm 80A retracts to move the U-shaped tip from the processing chamber 42 to the common transfer chamber 20.

Then, from time t58 to time t59, the pin (not shown) in the processing chamber 42 is lowered to place the semiconductor wafer W in a predetermined position in the processing chamber 42.

Through the above steps, the semiconductor wafer W is moved from the processing chamber 41 to the processing chamber 42.

In the fifth embodiment, the voltage V1 is applied between the electrodes 82 and 83 of the electrostatic chuck of the conveying arm 80A to generate an attraction force only while the conveying arm 80A is rotating, i.e., for the time period between time t53 and time t54. This method makes it possible to prevent “sticking” and eliminates the need to wait until the attraction force decreases (i.e., the time period between time t36 and time t37 in FIG. 11 is not necessary). Thus, the fifth embodiment makes it possible to improve the throughput of the substrate processing apparatus and also makes it possible to reduce power consumption. Here, it is assumed that the time period between time t30 and time t36 in FIG. 11 is the same as the time period between time t50 and time t56 in FIG. 12, and the time period between time t37 and time t40 in FIG. 11 is the same as the time period between time t56 and time t59 in FIG. 12.

The fifth embodiment is described using a process of moving the semiconductor wafer W from the processing chamber 41 to the processing chamber 42. However, the fifth embodiment may also be applied to a process of moving the semiconductor wafer W between any other combination of the processing chambers 41, 42, 43, and 44 and between the load lock chambers 31 and 32 and the processing chambers 41, 42, 43, and 44. Also, the fifth embodiment may be applied to the conveying arm 80B and the conveying arms 16A and 16B of the input-side conveying mechanism 16.

The present invention is not limited to the specifically disclosed embodiments, and variations and modifications may be made without departing from the scope of the present invention.

For example, although the above embodiments are described using a process of moving the semiconductor wafer W from the processing chamber 41 to the processing chamber 42, the above embodiments may also be applied to a process of moving the semiconductor wafer W between any other combination of the processing chambers 41, 42, 43, and 44 and between the load lock chambers 31 and 32 and the processing chambers 41, 42, 43, and 44. Also, the above embodiments may be applied to the conveying arm 80B and the conveying arms 16A and 16B of the input-side conveying mechanism 16.

As a variation of the above embodiments, the voltage V1 may be applied between the electrodes 82 and 83 of the electrostatic chuck while the conveying arms 80A and BOB holding the semiconductor wafers W are performing a sliding movement (see FIGS. 12 and 13), and a voltage of 0 V may be applied between the electrodes 82 and 83 of the electrostatic chuck while the conveying arms 80A and BOB are performing the extending and retracting movements. Here, the sliding movement indicates a horizontal movement of the entire conveying arms 80A and 80B.

When removing the attraction force of the electrostatic chuck by applying a reverse voltage, which has a polarity opposite to the polarity of the voltage for generating the attraction force, between the electrodes of the electrostatic chuck, the reverse voltage may be applied for a period of time that is sufficient to remove a charge remaining on the semiconductor wafer and the electrostatic chuck. Similarly, the period of time for applying a voltage of 0 V between the electrodes of the electrostatic chuck may be determined appropriately.

As a variation of the first, second, and third embodiments, instead of applying a voltage of 0 V between the electrodes 82 and 83 of the electrostatic chuck while the semiconductor wafer W is placed on the conveying arm 80A, the electrodes 82 and 83 may be opened as described in the fifth embodiment. In this case, a voltage of 0 V may be applied between the electrodes 82 and 83 before the semiconductor wafer W is transferred from the conveying arm 80A onto the pin in the processing chamber 42.

In the above embodiments, it is assumed that the electrostatic chuck of the conveying arm 80A is a Coulomb-type electrostatic chuck where the insulating layers 84 and 85 are formed on the electrodes 82 and 83. Alternatively, the electrostatic chuck of the conveying arm 80A may be implemented by a Johnson-Rahbek-type electrostatic chuck where dielectric layers with low conductivity are formed instead of the insulating layers 84 and 85.

When an electrostatic chuck such as a Johnson-Rahbek-type electrostatic chuck whose residual charge can be released by just opening the electrodes is used, it is not necessary to apply a voltage of 0 V and/or a reverse voltage between the electrodes in addition to opening the electrodes.

In the above embodiments, the substrate processing apparatus is implemented as a cluster tool that includes plural single-wafer processing chambers. However, the present invention may be applied to any other type of substrate processing apparatus including an electrostatic chuck for attracting a substrate, a conveying arm for conveying the substrate, and a controller that controls a voltage applied between the electrodes of the electrostatic chuck as described above according to the operational states (including the stationary state) of the conveying arm carrying the substrate.

The present international application claims priority from Japanese Patent Application No. 2009-256301 filed on Nov. 9, 2009, the entire contents of which are hereby incorporated herein by reference.

1. A substrate processing apparatus, comprising:
a conveying aim configured to convey a substrate placed thereon and including an electrostatic chuck for attracting the substrate placed on the conveying arm; and
a control unit configured to
not apply a voltage for causing the electrostatic chuck to attract the substrate between electrodes of the electrostatic chuck when the substrate is placed on the conveying arm but the conveying arm is not moving, and
apply the voltage between the electrodes of the electrostatic chuck when the substrate is placed on the conveying arm and the conveying arm is moving.

2. The substrate processing apparatus as claimed in claim 1, further comprising:
a plurality of processing chambers configured to process the substrate;
a transfer chamber connected to the processing chambers; and
a load lock chamber connected to the transfer chamber,
wherein the conveying arm is disposed in the transfer chamber and configured to move the substrate between the processing chambers and between the processing chambers and the load lock chamber.

3. The substrate processing apparatus as claimed in claim 1, further comprising:
a plurality of processing chambers configured to process the substrate;
a transfer chamber connected to the processing chambers;
a load lock chamber connected to the transfer chamber;
an atmospheric transfer chamber connected to the load lock chamber; and
an input port connected to the atmospheric transfer chamber and configured to receive a cassette housing plural substrates,
wherein the conveying arm is disposed in the atmospheric transfer chamber and configured to move the substrate between the load lock chamber and the input port.

4. A substrate processing apparatus, comprising:
a conveying arm including an electrostatic chuck for attracting a substrate placed on the conveying arm and configured to perform extending, retracting, and rotating movements to convey the substrate; and
a control unit configured to
not apply a voltage for causing the electrostatic chuck to attract the substrate between electrodes of the electrostatic chuck when the substrate is placed on the conveying arm and the conveying arm is performing the extending movement or the retracting movement, and
apply the voltage between the electrodes of the electrostatic chuck when the substrate is placed on the conveying arm and the conveying arm is performing the rotational movement.

5. The substrate processing apparatus as claimed in claim 4, further comprising:
a plurality of processing chambers configured to process the substrate;
a transfer chamber connected to the processing chambers; and
a load lock chamber connected to the transfer chamber,
wherein the conveying arm is disposed in the transfer chamber and configured to move the substrate between the processing chambers and between the processing chambers and the load lock chamber.

6. The substrate processing apparatus as claimed in claim 4, further comprising:
a plurality of processing chambers configured to process the substrate;
a transfer chamber connected to the processing chambers;
a load lock chamber connected to the transfer chamber;
an atmospheric transfer chamber connected to the load lock chamber; and
an input port connected to the atmospheric transfer chamber and configured to receive a cassette housing plural substrates,
wherein the conveying arm is disposed in the atmospheric transfer chamber and configured to move the substrate between the load lock chamber and the input port.

7. The substrate processing apparatus as claimed in claim 4, wherein
the conveying arm is configured to perform a sliding movement in addition to the extending, retracting, and rotational movements; and
the control unit is configured to apply the voltage for causing the electrostatic chuck to attract the substrate between the electrodes of the electrostatic chuck when the substrate is placed on the conveying arm and the conveying arm is performing the sliding movement.

8. The substrate processing apparatus as claimed in claim 1, wherein when not applying the voltage for causing the electrostatic chuck to attract the substrate between the electrodes of the electrostatic chuck, the control unit is configured to apply a voltage of 0 V between the electrodes.

9. The substrate processing apparatus as claimed in claim 4, wherein when not applying the voltage for causing the electrostatic chuck to attract the substrate between the electrodes of the electrostatic chuck, the control unit is configured to apply a voltage of 0 V between the electrodes of the electrostatic chuck.

10. The substrate processing apparatus as claimed in claim 1, wherein when not applying the voltage for causing the electrostatic chuck to attract the substrate between the electrodes of the electrostatic chuck, the control unit is configured to open the electrodes of the electrostatic chuck.

11. The substrate processing apparatus as claimed in claim 4, wherein when not applying the voltage for causing the electrostatic chuck to attract the substrate between the electrodes of the electrostatic chuck, the control unit is configured to open the electrodes of the electrostatic chuck.

12. A method of controlling a substrate processing apparatus that includes a conveying arm configured to convey a substrate placed thereon and including an electrostatic chuck for attracting the substrate placed on the conveying arm, the method comprising:
a step of placing the substrate on the conveying arm;
a first moving step of applying a voltage between electrodes of the electrostatic chuck of the conveying arm to attract the substrate to the conveying arm and causing the conveying arm to move the substrate;
a removing step, performed after the first moving step, of removing an attraction force of the electrostatic chuck of the conveying arm; and
a second moving step, performed after the removing step, of applying the voltage between the electrodes of the electrostatic chuck of the conveying arm to attract the substrate to the conveying arm and causing the conveying arm to move the substrate.

13. A method of controlling a substrate processing apparatus that includes a conveying arm configured to convey a substrate placed thereon and including an electrostatic chuck for attracting the substrate placed on the conveying arm, the method comprising:
a step of placing the substrate on the conveying arm;
a first moving step of causing the conveying arm to extend or retract to move the substrate without causing the electrostatic chuck to attract the substrate;
a rotating step, performed after the first moving step, of applying a voltage between electrodes of the electrostatic chuck of the conveying arm to attract the substrate to the conveying arm and causing the conveying arm to rotate, but not to extend or retract, to move the substrate;
a removing step, performed after the rotating step, of removing an attraction force of the electrostatic chuck of the conveying arm; and
a second moving step, performed after the removing step, of causing the conveying arm to extend or retract to move the substrate without causing the electrostatic chuck to attract the substrate.

14. The method as claimed in claim 13, further comprising:
a sliding step of applying the voltage between the electrodes of the electrostatic chuck of the conveying arm to attract the substrate to the conveying arm and causing the conveying arm to slide to move the substrate.

15. The method as claimed in claim 12, wherein in the removing step, a voltage of 0 V is applied between the electrodes of the electrostatic chuck.

16. The method as claimed in claim 12, wherein in the removing step, the electrodes of the electrostatic chuck are opened.

17. The method as claimed in claim 13, wherein in the removing step, a voltage having a polarity that is opposite to a polarity of the voltage applied to cause the electrostatic chuck to attract the substrate is applied between the electrodes of the electrostatic chuck.

18. The method as claimed in claim 13, wherein in the removing step, a voltage of 0 V is applied between the electrodes of the electrostatic chuck.

19. The method as claimed in claim 13, wherein in the removing step, the electrodes of the electrostatic chuck are opened.

20. The method as claimed in claim 13, wherein the removing step includes
applying a voltage, which has a polarity that is opposite to a polarity of the voltage applied to cause the electrostatic chuck to attract the substrate, between the electrodes of the electrostatic chuck; and
applying a voltage of 0 V between the electrodes of the electrostatic chuck.
